(19) United States
(12) Patent Application Publication
(10) Pub. No.: US 2026/0247783 A1
(43) Pub. Date: Aug. 20, 2026

(54) Photoelectric Conversion Device and Preparation Method Thereof

(71) Applicant: UNIVERSITY OF MACAU, Macau (CN)

(72) Inventors: Wei Hong, Macau (CN); Shu Xiao, Macau (CN); Peiyuan Pang, Macau (CN); Jia Guo, Macau (CN); Guichuan Xing, Macau (CN)

(21) Appl. No.: 19/175,287

(22) Filed: Apr. 10, 2025

(30) Foreign Application Priority Data
Feb. 18, 2025 (CN) 202510176453.8

(51) Int. Cl. H10K 30/85; H10K 30/50; H10K 30/86; H10K 50/15; H10K 50/16; H10K 85/50; H10K 101/40; H10K 102/00

(52) U.S. Cl. CPC H10K 30/85; H10K 30/50; H10K 30/86; H10K 50/156; H10K 50/166; H10K 85/50; H10K 2101/40; H10K 2102/351

(57) ABSTRACT

The present disclosure relates to a photoelectric conversion device and a preparation method thereof. The photoelectric conversion device includes a first electrode, a hole transport layer, a semiconductor functional layer, an electron transport layer, and a second electrode, which are stacked in order, wherein the conduction band energy level of the electron transport layer is matched with that of the semiconductor functional layer, and the valence band energy level of the electron transport layer is deeper than that of the semiconductor functional layer; and the valence band energy level of the hole transport layer is matched with that of the semiconductor functional layer, and the conduction band energy level of the hole transport layer is shallower than that of the semiconductor functional layer. The photoelectric conversion device of the present disclosure realizes the dual functions of photon-electricity conversion and electricity-photon conversion in a single device.

### CROSS-REFERENCE TO RELATED APPLICATION

This application claims priority to Chinese Patent Application No. 202510176453.8 filed Feb. 18, 2025, the disclosure of which is hereby incorporated by reference in its entirety.

### BACKGROUND

### Technical Field

The present disclosure belongs to the photoelectric technical field and relates to a photoelectric conversion device and a preparation method thereof.

### Technical Considerations

Metal halide perovskite has the characteristics of a long carrier diffusion length, a high fluorescence quantum yield, bipolar transmission, good absorption and luminescence, etc., and is widely used in the fields of solar cells, light-emitting diodes, etc. Perovskite solar cells and perovskite light-emitting diodes can both be constructed using conventional p-i-n and n-i-p structures. The difference is that in order to achieve efficient carrier extraction or carrier injection, it is necessary to design corresponding energy level structures. Therefore, as long as the structural design is rational, it is theoretically possible to realize photovoltaic and luminescent dual functions in the same device. However, traditional energy band structure design strategies for battery devices and light-emitting devices find it challenging to reconcile the two opposite needs of efficient charge extraction and injection. At present, only near-infrared band perovskite with a relatively narrow bandgap has achieved a relatively considerable reversible conversion efficiency, and the development of visible band perovskite dual-function devices with a wide bandgap, which are more widely used, is still greatly limited.

### SUMMARY

In order to overcome at least one of the above problems in the prior art, one of the objects of the present disclosure is to provide a photoelectric conversion device, which has both photovoltaic and luminescent characteristics and can realize photon-electricity conversion and electricity-photon conversion dual functions in a single device.

A second object of the present disclosure is to provide a method for preparing the above photoelectric conversion device.

A third object of the present disclosure is to provide a photoelectric conversion apparatus comprising the above photoelectric conversion device.

In order to achieve the above objects, the technical solution used by the present disclosure is as follows:
In a first non-limiting aspect of the present disclosure, there is provided a photoelectric conversion device, comprising a first electrode, a hole transport layer, a semiconductor functional layer, an electron transport layer, and a second electrode, which are stacked in order;
wherein a conduction band energy level of the electron transport layer is matched with a conduction band energy level of the semiconductor functional layer; a valence band energy level of the electron transport layer is deeper than a valence band energy level of the semiconductor functional layer; and
wherein a valence band energy level of the hole transport layer is matched with a valence band energy level of the semiconductor functional layer; a conduction band energy level of the hole transport layer is shallower than a conduction band energy level of the semiconductor functional layer.

In some non-limiting embodiments of the present disclosure, the semiconductor functional layer comprises a direct bandgap semiconductor material, and the direct bandgap semiconductor material comprises at least one of a metal halide perovskite, gallium nitride, cadmium selenide, or indium phosphide.

In some non-limiting embodiments of the present disclosure, the metal halide perovskite has a chemical formula of AMX₃ or L₂Aₙ₋₁MₙX₃ₙ₊₁;
wherein A represents a monovalent cation; A includes at least one of Cs⁺, Rb⁺, MA⁺, FA⁺, or GA⁺;
M represents a divalent cation; M includes at least one of Pb²⁺, Sn²⁺, Mn²⁺, Ca²⁺, or Zn²⁺;
X represents a monovalent anion; X includes at least one of F⁻, Cl⁻, Br⁻, I⁻, (BF₄)⁻, or SCN⁻;
L represents a monovalent cation; L includes at least one of EA⁺, PA⁺, i-PA⁺, BA⁺, i-BA⁺, t-BA⁺, HA⁺, OA⁺, PhA⁺, PMA⁺, PEA⁺, PPA⁺, or NMA⁺; and
n is 1 to 10.

In some non-limiting embodiments of the present disclosure, the electron transport layer comprises at least one of the following layer structures:
a first electron monolayer structure composed of a first electron transport layer;
a second electron multilayer structure composed of a first electron transport layer and a second electron transport layer, which are stacked;
a third electron multilayer structure composed of a first electron transport layer, a second electron transport layer and a third electron transport layer, which are stacked in order; and
a fourth electron multilayer structure composed of a first electron transport layer, a hybrid electron transport layer, a second electron transport layer, and a third electron transport layer, which are stacked in order;
wherein the first electron transport layer, the second electron transport layer, and the third electron transport layer each independently comprise at least one electron transport material; and
the hybrid electron transport layer comprises at least two electron transport materials.

In some non-limiting embodiments of the present disclosure, the electron transport layer comprises an electron transport material; and the electron transport material comprises at least one of 1,3,5-tris(1-phenyl-1H-benzimidazol-2-yl)benzene, 2,4,6-tris[3-(diphenylphosphino)phenyl]-1,3,5-triazine, 4,6-bis(3,5-bis(pyridin-3-yl)phenyl)-2-methylpyrimidine, 4,6-bis(3,5-bis(pyridin-4-yl)phenyl)-2-methylpyrimidine, tris[2,4,6-trimethyl-3-(3-pyridinyl)phenyl]borane, 2,9-dimethyl-4,7-biphenyl-1,10-phenanthroline, fullerene C₆₀, fullerene C₇₀, [6,6]-phenyl-C₆₁-butyric acid methyl ester, [6,6]-phenyl-C₇₁-butyric acid methyl ester, 2,7-bis(3-(dimethylamino) propyl)benzo[LMN][3,8]phenanthroline-1,3,6,8 (2H,7H)-tetrone, zinc oxide, or tin dioxide.

In some non-limiting embodiments of the present disclosure, the hole transport layer comprises at least one of the following layer structures:
a first hole monolayer structure composed of a first hole transport layer; and
a second hole multilayer structure composed of a first hole transport layer and a second hole transport layer, which are stacked;
wherein the first hole transport layer and the second hole transport layer each independently comprise at least one hole transport material.

In some non-limiting embodiments of the present disclosure, the hole transport layer comprises a hole transport material; and the hole transport material comprises at least one of poly(ethylenedioxythiophene)-poly(styrene sulfonate), nickel oxide, molybdenum trioxide, poly[bis(4-phenyl)(2,4,6-trimethylphenyl)amine], poly(9-vinylcarbazole), poly[(9,9-di-n-octylfluorenyl-2,7-diyl)-alt-(4,4′-(N-(4-n-butyl)phenyl)-diphenylamine)], 2,2′,7,7′-tetra[N,N-bis(4-methoxyphenyl)amino]-9,9′-spirobifluorene, [2-(9H-carbazol-9-yl)ethyl]phosphoric acid, [4-(9H-carbazol-9-yl)butyl]phosphoric acid, [2-(3,6-dimethoxy-9H-carbazol-9-yl)ethyl]phosphoric acid, [4-(3,6-dimethoxy-9H-carbazol-9-yl)butyl]phosphoric acid, or [4-(3,6-dimethyl-9H-carbazol-9-yl)butyl]phosphoric acid.

In some non-limiting embodiments of the present disclosure, the first electrode has a thickness of 1 nm to 200 nm.

In some non-limiting embodiments of the present disclosure, the hole transport layer has a thickness of 0.5 nm to 30 nm.

In some non-limiting embodiments of the present disclosure, the semiconductor functional layer has a thickness of 50 nm to 2000 nm.

In some non-limiting embodiments of the present disclosure, the electron transport layer has a thickness of 0.5 nm to 100 nm.

In some non-limiting embodiments of the present disclosure, the second electrode has a thickness of 1 nm to 200 nm.

In a second non-limiting aspect of the present disclosure, there is provided a method for preparing a photoelectric conversion device as described in the first aspect of the present disclosure, comprising the following step: sequentially preparing the first electrode, the hole transport layer, the semiconductor functional layer, the electron transport layer, and the second electrode to obtain the photoelectric conversion device.

In a third non-limiting aspect of the present disclosure, there is provided a photoelectric conversion apparatus, comprising the photoelectric conversion device as described in the first aspect of the present disclosure.

Beneficial Effects of the Disclosure: By means of the configuration of the hole transport layer and the electron transport layer in the photoelectric conversion device of the present disclosure, the energy level arrangement in the structure of the device is optimized, the extraction and injection of charges is balanced, the dissociation and recombination of excitons in the semiconductor functional layer is promoted, and/or photon-electricity conversion and electricity-photon conversion dual functions are realized in a single device.

### BRIEF DESCRIPTION OF THE DRAWINGS

FIG. 1 shows a schematic diagram of an energy level structure in some examples of the present disclosure;

FIG. 2 shows a schematic structural diagram of a photoelectric conversion device according to Example 1 of the present disclosure;

FIG. 3 shows an ultraviolet-visible absorption spectrum of an FAPbBr₃ perovskite layer in Example 1 of the present disclosure;

FIG. 4 shows a steady-state fluorescence spectrum of the FAPbBr₃ perovskite layer in Example 1 of the present disclosure;

FIG. 5 shows a scanning electron microscope image of the FAPbBr₃ perovskite layer in Example 1 of the present disclosure;

FIG. 6 shows the test results of the photovoltaic performance of the devices of Examples 1 and 2 of the present disclosure and Comparative Example 1;

FIG. 7 shows brightness-voltage curves of the devices of Examples 1 and 2 of the present disclosure and Comparative Example 1;

FIG. 8 shows external quantum efficiency-brightness curves of the devices of Examples 1 and 2 of the present disclosure; and

FIG. 9 shows an electroluminescence spectrum of the device of Example 2 of the present disclosure under different bias voltages.

### DETAILED DESCRIPTION

The content of the present disclosure will be further explained below in detail by non-limiting examples. It should also be understood that the following examples are only used to further illustrate the present disclosure and cannot be understood as limiting the scope of protection of the present disclosure. Some non-essential improvements and adjustments made by those skilled in the art according to the principles set forth in the present disclosure all fall within the scope of protection of the present disclosure. The specific process parameters, etc., in the following examples are also only illustrative in appropriate ranges, that is, those skilled in the art can make choices within the appropriate ranges by means of the description herein and are not intended to limit the specific data in the following examples. Unless otherwise specified, the raw materials, reagents, or apparatuses used in the following examples and comparative examples can all be obtained from conventional commercial channels or by existing known methods.

For the purposes of this specification, unless otherwise indicated, all numbers expressing quantities of ingredients, reaction conditions, dimensions, physical characteristics, and so forth used in the specification and claims are to be understood as being modified in all instances by the term “about.” Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Also, it should be understood that any numerical range recited herein is intended to include all sub-ranges subsumed therein. For example, a range of “1 to 10” is intended to include any and all sub-ranges between and including the recited minimum value of 1 and the recited maximum value of 10, that is, all subranges beginning with a minimum value equal to or greater than 1 and ending with a maximum value equal to or less than 10, and all subranges in between, e.g., 1 to 6.3, or 5.5 to 10, or 2.7 to 6.1.

Hereinafter, the terms “first” and “second” are only used for descriptive purposes and cannot be understood as indicating or implying relative importance or implicitly indicating the number of indicated technical features. Therefore, features defined with “first” and “second” may explicitly or implicitly include one or more of these features. As used in the description and the appended claims, the singular forms “a/an” and “the” also include plural referents, unless the content clearly indicates otherwise. In the description of the examples of the present disclosure, unless otherwise specified, “at least one” means one or more, and “at least two” means two or more.

In a first non-limiting aspect of the examples of the present disclosure, there is provided a photoelectric conversion device, comprising a first electrode, a hole transport layer, a semiconductor functional layer, an electron transport layer, and a second electrode, which are stacked in order,
wherein the conduction band energy level of the electron transport layer is matched with that of the semiconductor functional layer, and the valence band energy level of the electron transport layer is deeper than that of the semiconductor functional layer; and
wherein the valence band energy level of the hole transport layer is matched with that of the semiconductor functional layer, and the conduction band energy level of the hole transport layer is shallower than that of the semiconductor functional layer.

The valence band energy level refers to the energy level in the band that has the highest energy in the fully filled band occupied by valence electrons; the conduction band energy level refers to the lowest energy level in the conduction band that some electrons can reach after crossing the forbidden band and entering the empty band having higher energy; and there is a bandgap between the conduction band energy level and the valence band energy level.

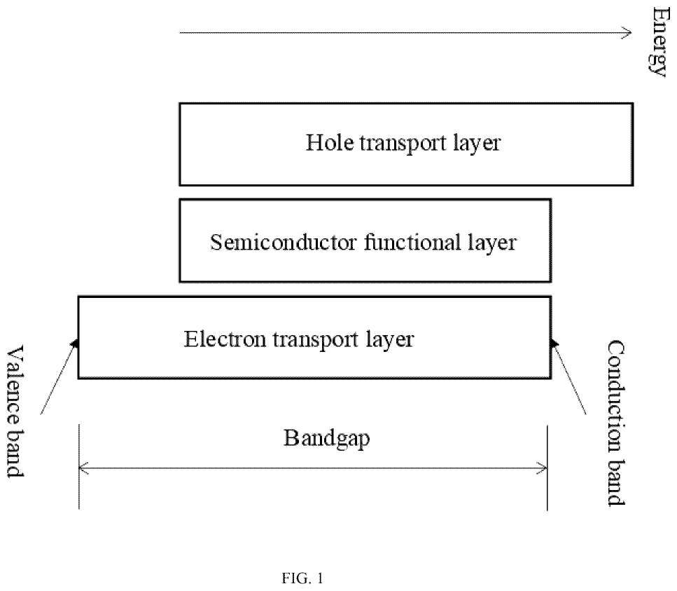

The schematic diagram of the energy level structure in some examples of the present disclosure is as shown in FIG. 1. In the above examples, by means of the configuration of the electron transport layer, the conduction band energy level of the electron transport layer is matched with that of the semiconductor functional layer, which is beneficial for the electron transport layer to be able to not only inject electrons into the semiconductor functional layer but also extract electrons. Moreover, the electron transport layer has a deeper valence band energy level than the semiconductor functional layer, which makes it possible to effectively block holes from the semiconductor functional layer and prevent hole leakage. Furthermore, by means of the configuration of the hole transport layer, the valence band energy level of the hole transport layer is matched with that of the semiconductor functional layer, which is beneficial for the hole transport layer to be able to not only inject holes into the semiconductor functional layer but also extract holes. Moreover, the hole transport layer has a shallower conduction band energy level than the semiconductor functional layer, which makes it possible to effectively block electrons from the semiconductor functional layer and prevent electron leakage.

In the above examples, energy level matching means that the energy level difference between two energy levels is less than or equal to 0.5 eV.

For example, the matching between the conduction band energy level of the electron transport layer and that of the semiconductor functional layer means that the energy level difference between the conduction band energy level of the electron transport layer and that of the semiconductor functional layer is less than or equal to 0.5 eV and may be any one of or a value in a range between any two of 0 eV, 0.1 eV, 0.2 eV, 0.3 eV, 0.4 eV, or 0.5 eV. The conduction band energy level of the electron transport layer may be slightly higher or slightly lower than, or equal to that of the semiconductor functional layer.

As another example, the matching between the valence band energy level of the hole transport layer and that of the semiconductor functional layer means that the energy level difference between the valence band energy level of the hole transport layer and that of the semiconductor functional layer is less than or equal to 0.5 eV and may be any one of or a value in a range between any two of 0 eV, 0.1 eV, 0.2 eV, 0.3 eV, 0.4 eV, or 0.5 eV. The valence band energy level of the hole transport layer may be slightly higher or slightly lower than or equal to that of the semiconductor functional layer.

Referring to FIG. 1, the values of the valence band energy levels of the electron transport layer and the semiconductor functional layer are both negative, so the difference between the valence band energy levels of the electron transport layer and the semiconductor functional layer is greater than the hole blocking threshold. That is, the valence band energy level of the electron transport layer is deep enough relative to that of the semiconductor functional layer, hole leakage can be prevented. The hole blocking threshold here refers to the energy level value that can impart the electron transport layer with the desired hole blocking function and can be determined according to actual needs.

Further referring to FIG. 1, the values of the conduction band energy levels of the hole transport layer and the semiconductor functional layer are both negative, so the difference between the conduction band energy levels of the hole transport layer and the semiconductor functional layer is greater than the electron blocking threshold. That is, the conduction band energy level of the hole transport layer is shallow enough relative to that of the semiconductor functional layer, electron leakage can be prevented. The electron blocking threshold here refers to the energy level value that can impart the hole transport layer with the desired electron blocking function and can be determined according to actual needs.

By means of the configuration of the hole transport layer and the electron transport layer in the photoelectric conversion device of the present disclosure, the energy level arrangement in the structure of the device is optimized, the extraction and injection of charges is balanced, the dissociation and recombination of excitons in the semiconductor functional layer is promoted, and photon-electricity conversion and electricity-photon conversion dual functions are realized in a single device. When the device is irradiated by an external light source, the semiconductor functional layer can absorb photon energy to form excitons. In addition, free electrons and holes formed by exciton dissociation can be extracted respectively by the electron transport layer and the hole transport layer and migrate to a cathode and an anode, thereby forming a current in the circuit. When the device is excited by an external voltage, electrons and holes can be in turn injected into the perovskite layer from the electron transport layer and the hole transport layer, respectively, to emit light by radiative recombination. The photoelectric conversion device thus obtained can spontaneously realize the recycling of energy.

In some examples of the present disclosure, the semiconductor functional layer comprises a direct bandgap semiconductor material.

In some examples of the present disclosure, the direct bandgap semiconductor material comprises at least one of a metal halide perovskite, gallium nitride, cadmium selenide, or indium phosphide. In some non-limiting examples of the present disclosure, the direct bandgap semiconductor material is selected from a metal halide perovskite.

In some examples of the present disclosure, the structure of the metal halide perovskite comprises at least one of a three-dimensional perovskite structure (AMX₃), a two-dimensional perovskite structure (L₂Aₙ₋₁MₙX₃ₙ₊₁), a quasi-two-dimensional perovskite structure (L₂Aₙ₋₁MₙX₃ₙ₊₁), or a perovskite nanocrystal structure.

In the above examples, for the three-dimensional perovskite structure, inorganic layer materials are interconnected by [MX₆]⁴⁻ octahedrons, and A ions are embedded in the gaps between adjacent octahedrons. For two-dimensional or quasi-two-dimensional perovskite structures, inorganic layer materials are embedded and separated by L ions to form quantum wells with different values of n, with n representing the number of layers of [MX₆]⁴⁻. For the perovskite nanocrystal structure, perovskite is wrapped by large-size organic cations or metal ion ligands, forming nano-scaled perovskite crystals.

In some examples of the present disclosure, the semiconductor functional layer prepared by using the metal halide perovskite has good light absorption and luminescent characteristics. The metal halide perovskite can absorb photon energy to generate excitons, and the excitons dissociate to form free electrons and holes, thus realizing a photovoltaic function; in addition, the free electrons and holes can in turn attract each other under excitation by an external voltage to form excitons, and the excitons generate photons by radiative recombination, thereby realizing a luminescent function, so that the device can realize photovoltaic-luminescent dual functions in different scenarios.

In some examples of the present disclosure, the metal halide perovskite has a chemical formula of AMX₃ or L₂Aₙ₋₁MₙX₃ₙ₊₁;
wherein A represents a monovalent cation; A includes at least one of Cs⁺ (cesium ion), Rb⁺ (rubidium ion), MA⁺ (methylammonium ion), FA⁺ (formamidinium ion), or GA⁺ (guanidinium ion);
M represents a divalent cation; M includes at least one of Pb²⁺ (lead ion), Sn²⁺ (tin ion), Mn²⁺ (manganese ion), Ca²⁺ (calcium ion), or Zn²⁺ (zinc ion);
X represents a monovalent anion; X includes at least one of F⁻ (fluoride ion), Cl⁻ (chloride ion), Br⁻ (bromide ion), I⁻ (iodide ion), (BF₄)⁻ (tetrafluoroborate ion), or SCN⁻ (thiocyanate ion);
L represents a monovalent cation; L includes at least one of EA⁺ (ethylammonium ion), PA⁺ (propylammonium ion), i-PA⁺ (isopropylammonium ion), BA⁺ (butylammonium ion), i-BA⁺ (isobutylammonium ion), t-BA⁺ (tert-butylammonium ion), HA⁺ (hexylammonium ion), OA⁺ (octylammonium ion), PhA⁺ (phenylammonium ion), PMA⁺ (benzylammonium ion), PEA⁺ (phenylethylammonium ion), PPA⁺ (phenylpropylammonium ion), or NMA⁺ (naphthylmethylammonium ion); and
n is 1 to 10.

In the above examples, the chemical formula of the metal halide perovskite and the types of the ions are only illustrative, and those skilled in the art can make choices according to actual needs so as to implement the specific energy level structure of the present disclosure.

In some non-limiting examples of the present disclosure, the direct bandgap semiconductor material is selected from a wide-bandgap direct bandgap semiconductor material. In some examples of the present disclosure, the bandgap of the above wide-bandgap direct bandgap semiconductor material is 1.65 eV to 3.10 eV and may be, for example, any one of or a value in a range between any two of 1.65 eV, 1.8 eV, 2.0 eV, 2.2 eV, 2.5 eV, 2.8 eV, 3.0 eV, or 3.1 eV. In some non-limiting examples of the present disclosure, the direct bandgap semiconductor material is selected from FAPbBr₃.

A device obtained by using a semiconductor functional layer prepared using a wide-bandgap direct bandgap semiconductor material has an electroluminescent spectrum that can be in the visible range. For example, FAPbBr₃ has a bandgap of 2.28 eV, which corresponds to green light emission.

In some examples of the present disclosure, the thickness of the semiconductor functional layer is 50 nm to 2000 nm and may be, for example, any one of or a value in a range between any two of 50 nm, 80 nm, 100 nm, 300 nm, 500 nm, 800 nm, 1000 nm, 1500 nm, or 2000 nm.

In some examples of the present disclosure, the first electrode and the second electrode each independently comprise a transparent electrode, a metal electrode, or a combination thereof. In some non-limiting examples of the present disclosure, the first electrode and the second electrode each independently comprise at least one of an ITO electrode, an FTO electrode, a gold electrode, a silver electrode, a copper electrode, an aluminum electrode, or a platinum electrode.

The selection of the first electrode and the second electrode can be specifically adjusted according to actual needs. For example, the first electrode is a transparent electrode and the second electrode is a metal electrode, so that a p-i-n structure can be prepared. For example, the first electrode is a metal electrode and the second electrode is a transparent electrode, so that an n-i-p structure can be prepared; furthermore, alternatively, a structure of a transparent electrode combined with a metal electrode can be used, and the combination form can be at least one of doping, hybridization, or stacking. The first electrode and the second electrode can be specifically configured by those skilled in the art according to actual needs, which is not specifically defined in the present disclosure.

In some examples of the present disclosure, the first electrode is selected from an ITO electrode; and the second electrode is selected from an Ag electrode.

In some examples of the present disclosure, the thickness of the first electrode is 1 nm to 200 nm and may be, for example, any one of or a value in a range between any two of 1 nm, 5 nm, 10 nm, 50 nm, 80 nm, 100 nm, 150 nm, or 200 nm.

In some examples of the present disclosure, the thickness of the second electrode is 1 nm to 200 nm and may be, for example, any one of or a value in a range between any two of 1 nm, 5 nm, 10 nm, 50 nm, 80 nm, 100 nm, 150 nm, or 200 nm.

In some examples of the present disclosure, the electron transport layer comprises at least one electron transport material. Furthermore, when the electron transport layer comprises at least two electron transport materials, the combination form of the electron transport materials includes at least one of doping, hybridization, or stacking.

In some examples of the present disclosure, the electron transport layer comprises at least one of the following layer structures:
a first electron monolayer structure composed of a first electron transport layer;
a second electron multilayer structure composed of a first electron transport layer and a second electron transport layer, which are stacked;
a third electron multilayer structure composed of a first electron transport layer, a second electron transport layer and a third electron transport layer, which are stacked in order; and
a fourth electron multilayer structure composed of a first electron transport layer, a hybrid electron transport layer, a second electron transport layer, and a third electron transport layer, which are stacked in order;
wherein the first electron transport layer, the second electron transport layer, and the third electron transport layer each independently comprise at least one electron transport material; and the hybrid electron transport layer comprises at least two electron transport materials.

In the above examples, when the first electron transport layer, the second electron transport layer, and the third electron transport layer each independently comprise at least two electron transport materials, the combination form of the electron transport materials includes doping or hybridization. In the hybrid electron transport layer, the combination form of the electron transport materials includes doping or hybridization.

In some examples of the present disclosure, the electron transport layer comprises an electron transport material; and the electron transport material comprises at least one of 1,3,5-tris(1-phenyl-1H-benzimidazol-2-yl)benzene (TPBi), 2,4,6-tris[3-(diphenylphosphino)phenyl]-1,3,5-triazine (PO-T2T), 4,6-bis(3,5-bis(pyridin-3-yl)phenyl)-2-methylpyrimidine (B3PYMPM), 4,6-bis(3,5-bis(pyridin-4-yl)phenyl)-2-methylpyrimidine (B4PYMPM), tris[2,4,6-trimethyl-3-(3-pyridinyl)phenyl]borane (3TPYMB), 2,9-dimethyl-4,7-biphenyl-1,10-phenanthroline (BCP), fullerene C₆₀ (C₆₀), fullerene C₇₀ (C₇₀), [6,6]-phenyl-C₆₁-butyric acid methyl ester (PC₆₁BM), [6,6]-phenyl-C₇₁-butyric acid methyl ester (PC₇₁BM), 2,7-bis(3-(dimethylamino) propyl)benzo[LMN][3,8]phenanthroline-1,3,6,8 (2H,7H)-tetrone (NDI-N), zinc oxide (ZnO), or tin dioxide (SnO₂).

In the above examples, the types of the electron transport materials are only illustrative, and those skilled in the art can make choices according to actual needs, so as to obtain an electron transport layer with a specific energy level structure and realize matching with the semiconductor functional layer.

In some non-limiting examples of the present disclosure, when the direct bandgap semiconductor material is selected from a wide-bandgap direct bandgap semiconductor material (such as FAPbBr₃), the electron transport layer is selected from the following layer structures: a third electron multilayer structure composed of a first electron transport layer, a second electron transport layer and a third electron transport layer, which are stacked in order.

In the above non-limiting examples, the electron transport layer is a combination of different layer structures, which can better match the wide-bandgap direct bandgap semiconductor material, thus realizing a specific energy level arrangement.

In some examples of the present disclosure, in the above third electron multilayer structure, the electron transport material in the first electron transport layer is selected from B4PYMPM, the electron transport material in the second electron transport layer is selected from C₆₀, and the electron transport material in the third electron transport layer is selected from BCP.

It should be noted that in the above examples, the selection of the electron transport materials in the first electron transport layer, the second electron transport layer and the third electron transport layer is only illustrative, and those skilled in the art can achieve a good effect of matching with the wide-bandgap direct bandgap semiconductor material according to the combination of different electron transport materials.

In some other non-limiting examples of the present disclosure, when the direct bandgap semiconductor material is selected from a wide-bandgap direct bandgap semiconductor material (such as FAPbBr₃), the electron transport layer is selected from the following layer structures: a fourth electron multilayer structure composed of a first electron transport layer, a hybrid electron transport layer, a second electron transport layer, and a third electron transport layer, which are stacked in order.

In the above non-limiting examples, by arranging a hybrid electron transport layer between the first electron transport layer and the second electron transport layer, the overall energy level structure of the electron transport layer can be further optimized, and an effect of better matching with the wide-bandgap direct bandgap semiconductor material can be achieved, thereby improving the performance of the device.

In some examples of the present disclosure, in the above fourth electron multilayer structure, the electron transport material in the first electron transport layer is selected from B4PYMPM, the electron transport material in the hybrid electron transport layer is selected from a mixture of B4PYMPM and C₆₀, the electron transport material in the second electron transport layer is selected from C₆₀, and the electron transport material in the third electron transport layer is selected from BCP.

It should be noted that in the above examples, the selection of the electron transport materials in the first electron transport layer, the hybrid electron transport layer, the second electron transport layer and the third electron transport layer is only illustrative. Those skilled in the art can achieve a good effect of matching with the wide-bandgap direct bandgap semiconductor material according to the combination of different electron transport materials.

In some examples of the present disclosure, the thickness of the electron transport layer is 0.5 nm to 100 nm and may be, for example, any one of or a value in a range between any two of 0.5 nm, 1 nm, 5 nm, 10 nm, 20 nm, 30 nm, 50 nm, 80 nm, or 100 nm.

In some non-limiting examples of the present disclosure, the thickness of the first electron transport layer is 0.5 nm to 20 nm and may be, for example, any one of or a value in a range between any two of 0.5 nm, 1 nm, 3 nm, 5 nm, 8 nm, 10 nm, 15 nm, 18 nm, or 20 nm.

In some non-limiting examples of the present disclosure, the thickness of the hybrid electron transport layer is 0 nm to 20 nm and may be, for example, any one of or a value in a range between any two of 0 nm, 0.5 nm, 1 nm, 3 nm, 5 nm, 8 nm, 10 nm, 15 nm, 18 nm, or 20 nm.

In some examples of the present disclosure, the hybrid electron transport layer comprises a first electron transport material and a second electron transport material, wherein the mass ratio of the first electron transport material to the second electron transport material is (0.1 to 10): 1 and may be, for example, any one of or a value in a range between any two of 0.1:1, 0.3:1, 0.5:1, 1:1, 3:1, 5:1, 8:1, or 10:1.

In some non-limiting examples of the present disclosure, the thickness of the second electron transport layer is 5 nm to 30 nm and may be, for example, any one of or a value in a range between any two of 5 nm, 8 nm, 10 nm, 15 nm, 18 nm, 20 nm, 22 nm, 25 nm, or 30 nm.

In some non-limiting examples of the present disclosure, the thickness of the third electron transport layer is 0.5 nm to 20 nm and may be, for example, any one of or a value in a range between any two of 0.5 nm, 1 nm, 3 nm, 5 nm, 8 nm, 10 nm, 15 nm, 18 nm, or 20 nm.

In some examples of the present disclosure, the hole transport layer comprises at least one hole transport material; furthermore, when the hole transport layer comprises at least two hole transport materials, the combination form of the hole transport materials includes at least one of doping, hybridization, or stacking.

In some examples of the present disclosure, the hole transport layer comprises at least one of the following layer structures: a first hole monolayer structure composed of a first hole transport layer; and a second hole multilayer structure composed of a first hole transport layer and a second hole transport layer, which are stacked;
wherein the first hole transport layer and the second hole transport layer each independently comprise at least one hole transport material.

In the above examples, when the first hole transport layer and the second hole transport layer each independently comprise at least two hole transport materials, the combination form of the hole transport materials includes doping or hybridization.

In some examples of the present disclosure, the hole transport layer comprises a hole transport material; and the hole transport material comprises at least one of poly(ethylenedioxythiophene)-poly(styrene sulfonate) (PEDOT:PSS), nickel oxide (NiOₓ), molybdenum trioxide (MoO₃), poly[bis(4-phenyl)(2,4,6-trimethylphenyl)amine] (PTAA), poly(9-vinylcarbazole) (PVK), poly[(9,9-di-n-octylfluorenyl-2,7-diyl)-alt-(4,4′-(N-(4-n-butyl)phenyl)-diphenylamine)] (TFB), 2,2′,7,7′-tetra[N,N-bis(4-methoxyphenyl)amino]-9,9′-spirobifluorene (Spiro-OMeTAD), [2-(9H-carbazol-9-yl)ethyl]phosphoric acid (2PACz), [4-(9H-carbazol-9-yl)butyl]phosphoric acid (4PACz), [2-(3,6-dimethoxy-9H-carbazol-9-yl)ethyl]phosphoric acid (MeO-2PACz), [4-(3,6-dimethoxy-9H-carbazol-9-yl)butyl]phosphoric acid (MeO-4PACz), or [4-(3,6-dimethyl-9H-carbazol-9-yl)butyl]phosphoric acid (Me-4PACz).

In the above examples, the types of the hole transport materials are only illustrative, and those skilled in the art can make choices according to actual needs, so as to obtain a hole transport layer with a specific energy level structure and realize matching with the semiconductor functional layer.

In some examples of the present disclosure, in the second hole multilayer structure, the hole transport material of the first hole transport layer comprises at least one of poly(ethylenedioxythiophene)-poly(styrene sulfonate) (PEDOT:PSS), nickel oxide (NiOₓ), molybdenum trioxide (MoO₃), poly[bis(4-phenyl)(2,4,6-trimethylphenyl)amine] (PTAA), poly(9-vinylcarbazole) (PVK), poly[(9,9-di-n-octylfluorenyl-2,7-diyl)-alt-(4,4′-(N-(4-n-butyl)phenyl)-diphenylamine)] (TFB), and 2,2′,7,7′-tetra[N,N-bis(4-methoxyphenyl)amino]-9,9′-spirobifluorene (Spiro-OMeTAD); and the hole transport material of the second hole transport layer comprises at least one of [2-(9H-carbazol-9-yl)ethyl]phosphoric acid (2PACz), [4-(9H-carbazol-9-yl)butyl]phosphoric acid (4PACz), [2-(3,6-dimethoxy-9H-carbazol-9-yl)ethyl]phosphoric acid (MeO-2PACz), [4-(3,6-dimethoxy-9H-carbazol-9-yl)butyl]phosphoric acid (MeO-4PACz), and [4-(3,6-dimethyl-9H-carbazol-9-yl)butyl]phosphoric acid (Me-4PACz).

When the hole transport layer comprises a second hole multilayer structure, the use of the combination of the above hole transport materials is beneficial to achieve a better energy level matching effect.

In some non-limiting examples of the present disclosure, when the semiconductor functional layer comprises a wide-bandgap direct bandgap semiconductor material (such as FAPbBr₃), the hole transport layer is selected from the following layer structures: a second hole multilayer structure composed of a first hole transport layer and a second hole transport layer, which are stacked.

In the above non-limiting examples, the hole transport layer is a combination of different layer structures, which can better match the wide-bandgap direct bandgap semiconductor material, thus realizing a specific energy level arrangement.

In some examples of the present disclosure, in the above second hole multilayer structure, the hole transport material in the first hole transport layer is selected from nickel oxide (NiOₓ), and the hole transport material in the second hole transport layer is selected from [2-(9H-carbazol-9-yl)ethyl]phosphoric acid (2PACz).

It should be noted that in the above examples, the selection of the hole transport materials in the first hole transport layer and the second hole transport layer is only illustrative, and those skilled in the art can achieve a good effect of matching with the wide-bandgap direct bandgap semiconductor material according to the combination of different hole transport materials.

In some examples of the present disclosure, the thickness of the hole transport layer is 0.5 nm to 30 nm and may be, for example, any one of or a value in a range between any two of 0.5 nm, 1 nm, 5 nm, 10 nm, 15 nm, 18 nm, 20 nm, 25 nm, or 30 nm.

In some non-limiting examples of the present disclosure, the thickness of the first hole transport layer is 0.5 nm to 15 nm and may be, for example, any one of or a value in a range between any two of 0.5 nm, 1 nm, 3 nm, 5 nm, 8 nm, 10 nm, 12 nm, or 15 nm.

In some non-limiting examples of the present disclosure, the thickness of the second hole transport layer is 0.5 nm to 15 nm and may be, for example, any one of or a value in a range between any two of 0.5 nm, 1 nm, 3 nm, 5 nm, 8 nm, 10 nm, 12 nm, or 15 nm.

In a second non-limiting aspect of the examples of the present disclosure, there is provided a method for preparing a photoelectric conversion device as described in the first aspect of the present disclosure, comprising the following step: sequentially preparing the first electrode, the hole transport layer, the semiconductor functional layer, the electron transport layer, and the second electrode to obtain the photoelectric conversion device.

The devices provided in the examples of the present disclosure have a simple preparation method and a low cost, can be miniaturized and integrated, and have a good application potential in the fields of photovoltaics, lighting, display, etc.

In some examples of the present disclosure, the methods for preparing the first electrode, the hole transport layer, the semiconductor functional layer, the electron transport layer, and the second electrode are each independently a deposition method.

In some non-limiting examples of the present disclosure, the deposition methods used for preparing the first electrode, the hole transport layer, the electron transport layer and the second electrode include at least one of magnetron sputtering, atomic layer deposition, vacuum thermal evaporation, electron beam evaporation, chemical vapor deposition, or solution spin coating; and the deposition method used for preparing the semiconductor functional layer includes at least one of spin coating, scrape coating, spraying, printing, inkjet printing, and evaporation.

In some examples of the present disclosure, when the semiconductor functional layer comprises a direct bandgap semiconductor material, the direct bandgap semiconductor material is selected from a metal halide perovskite, and the chemical formula of the metal halide perovskite is AMX₃ or L₂Aₙ₋₁MₙX₃ₙ₊₁, the method for preparing the semiconductor functional layer comprises: depositing a mixture comprising a halide of A, a halide of M, and an additive on the hole transport layer or depositing a mixture comprising a halide of L, a halide of A, a halide of M, and an additive on the hole transport layer; and carrying out a post-treatment to obtain the semiconductor functional layer.

In some non-limiting examples of the present disclosure, in the above method for preparing the semiconductor functional layer, the halide of A comprises at least one of CsCl, RbCl, MACl, FACl, GACl, CsBr, RbBr, MABr, FABr, GABr, CsI, RbI, MAl, FAl, or GAl.

In some non-limiting examples of the present disclosure, in the method for preparing the semiconductor functional layer, the halide of M comprises at least one of PbCl₂, SnCl₂, MnCl₂, CaCl₂, ZnCl₂, PbBr₂, SnBr₂, MnBr₂, CaBr₂, ZnBr₂, PbI₂, SnI₂, MnI₂, CaI₂, or ZnI₂.

In some non-limiting examples of the present disclosure, in the above method for preparing the semiconductor functional layer, the halide of L comprises at least one of ethylamine hydrochloride (EACl), propylamine hydrochloride (PACl), isopropylamine hydrochloride (i-PACl), butylamine hydrochloride (BACl), isobutylamine hydrochloride (i-BACl), tert-butylamine hydrochloride (t-BACl), hexylamine hydrochloride (HACl), octylamine hydrochloride (OACl), phenylmethylamine hydrochloride (PMACl), phenylethylamine hydrochloride (PEACl), phenylpropamine hydrochloride (PPACl), ethylamine hydrobromide (EABr), propylamine hydrobromide (PABr), isopropylamine hydrobromide (i-PABr), butylamine hydrobromide (BABr), isobutylamine hydrobromide (i-BABr), tert-butylamine hydrobromide (t-BABr), hexylamine hydrobromide (HABr), octylamine hydrobromide (OABr), aniline hydrobromide (PhABr), phenylethylamine hydrobromide (PMABr), phenylethylamine hydrobromide (PEABr), phenylpropamine hydrobromide (PPABr), naphthylmethylamine hydrobromide (NMABr), ethylamine hydroiodide (EAl), propylamine hydroiodide (PAl), isopropylamine hydroiodide (i-PAl), butylamine hydroiodide (BAl), isobutylamine hydroiodide (i-BAl), tert-butylamine hydroiodide (t-BAl), hexylamine hydroiodide (HAl), octylamine hydroiodide (OAl), aniline hydroiodide (PhAl), phenylmethylamine hydroiodide (PMAl), phenylethylamine hydroiodide (PEAl), phenylpropylamine hydroiodide (PPAl), or naphthylmethylamine hydroiodide (NMAl).

In some non-limiting examples of the present disclosure, in the above method for preparing the semiconductor functional layer, the additive comprises at least one of carboxylic acid molecules, phosphoric acid molecules, sulfonic acid molecules, pyridine molecules, thiophene molecules, pyrrole molecules, or silane molecules.

In some non-limiting examples of the present disclosure, in the above method for preparing the semiconductor functional layer, the method for depositing the mixture on the hole transport layer comprises at least one of spin coating, scrape coating, spraying, printing, inkjet printing, and evaporation. In some examples of the present disclosure, in the above method for preparing the semiconductor functional layer, the method for depositing the mixture on the hole transport layer specifically comprises: spin-coating the mixture as a solution on the hole transport layer at a spin coating speed of 500 rpm to 6000 rpm, wherein the above spin coating speed may be any one of or a value in a range between any two of 500 rpm, 1000 rpm, 2000 rpm, 4000 rpm, or 6000 rpm, e.g., 500 rpm to 4000 rpm.

In some non-limiting examples of the present disclosure, in the above method for preparing the semiconductor functional layer, the post-treatment comprises at least one of no treatment, thermal annealing treatment, solvent treatment, or vacuum treatment.

In some examples of the present disclosure, the method for preparing the above photoelectric conversion device comprises the following steps:
depositing a hole transport layer on a surface of a first electrode to obtain the hole transport layer;
depositing a mixture comprising a halide of A, a halide of M, and an additive on the hole transport layer; or depositing a mixture comprising a halide of L, a halide of A, a halide of M, and an additive on the hole transport layer; and carrying out a post-treatment to obtain the semiconductor functional layer;
on the semiconductor functional layer, depositing an electron transport layer and a second electrode layer by layer to prepare the above photoelectric conversion device.

The preparation method provided in the above examples is simple in process and easy to operate, and the thickness of each layer structure can be adjusted, which is beneficial to the preparation of a photoelectric conversion device with a superior performance.

In a third non-limiting aspect of the examples of the present disclosure, there is provided a photoelectric conversion apparatus, comprising the photoelectric conversion device as described in the first aspect of the present disclosure.

The photoelectric conversion device provided by the present disclosure can be used for preparing a photoelectric conversion apparatus, such as a photovoltaic apparatus (such as a solar cell), a lighting apparatus (such as a light-emitting diode), a display device, a light detector, etc., and the photoelectric conversion apparatus has both photovoltaic and luminescent characteristics, can sensitively respond to light signals, efficiently generates electricity under illumination, emits light with a low energy consumption under dark conditions, and has an efficient application effect.

The implementation of the present disclosure will be further described below in detail with reference to non-limiting examples and comparative examples.

### Example 1

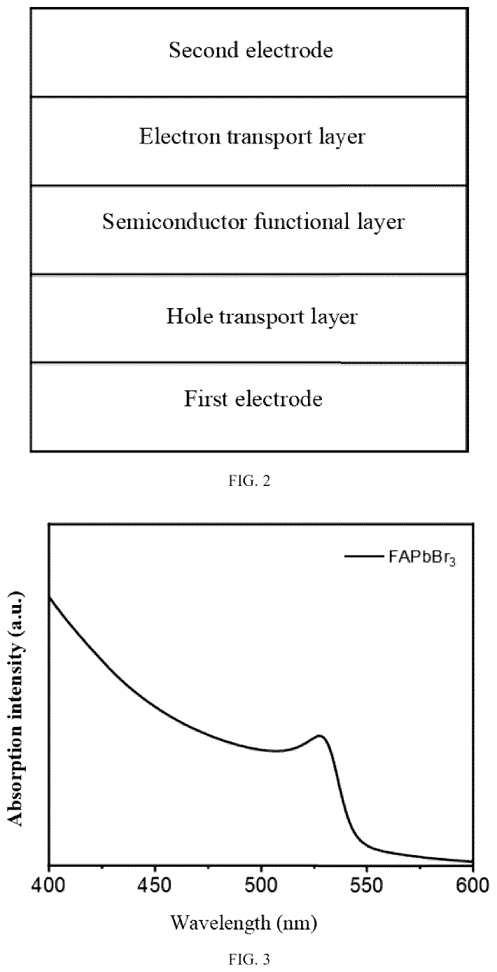

This example provided a photoelectric conversion device, as shown in the structural schematic diagram in FIG. 2, comprising: sequentially from bottom to top, an ITO electrode layer (180 nm); a hole transport combination layer composed of a first hole transport layer (NiOₓ, 15 nm) and a second hole transport layer (2PACz, about 1 nm), which were stacked in order; a three-dimensional perovskite FAPbBr₃ layer (270 nm); an electron transport combination layer composed of a first electron transport layer (B4PYMPM, 5 nm), a second electron transport layer (C₆₀, 20 nm), and a third electron transport layer (BCP, 5 nm), which were stacked in order; and a silver electrode layer (100 nm). The preparation process for the above device was as follows:
(1) 0.1 mol/L solution of nickel acetate tetrahydrate in ethanol was prepared, and 0.1 mol/L ethanolamine was added to obtain an NiOₓ precursor solution. The NiOₓ precursor solution was dropwise added to an ITO substrate, spin-coated at a speed of 4000 rpm for 30 seconds, and annealed at 360° C. for 60 minutes to obtain an NiOₓ layer.
(2) 0.5 mg/mL solution of 2PACz in ethanol was prepared. The solution of 2PACz in ethanol was dropwise added to the NiOₓ layer prepared in step (1), spin-coated at a speed of 4000 rpm for 30 seconds, and annealed at 100° C. for 10 minutes to obtain a 2PACz layer.
(3) 0.13747 g of formamidine hydrobromide (FABr), 0.36701 g of lead bromide (PbBr₂), 0.00123 g of potassium 3-sulfopropyl methacrylate (SPM), 0.85 mL of dimethyl sulfoxide (DMSO), and 0.15 mL of N,N-dimethylformamide (DMF) were accurately weighed into a glass flask, and stirred overnight at room temperature to fully dissolve the solute, so as to prepare a perovskite precursor solution.
(4) The perovskite precursor solution prepared in step (3) was dropwise added to the 2PACz layer prepared in step (2) and spin-coated firstly at a speed of 500 rpm for 5 seconds and then at a speed of 4000 rpm for 20 seconds, 120 μL of a mixed solvent of chlorobenzene/ethyl acetate (v/v=3:1) was dropwise added 10 seconds before the end of the second step of spin-coating, and after annealing at 90° C. for 10 minutes, a perovskite layer was obtained.
(5) 5 nm B4PYMPM, 20 nm C₆₀, 5 nm BCP, and a 100 nm Ag electrode were evaporated layer by layer on the perovskite layer prepared in step (4) by a vacuum thermal evaporation method to obtain the photoelectric conversion device of this example.

### Example 2

This example provided a photoelectric conversion device, comprising: sequentially from bottom to top, an ITO electrode layer (180 nm); a hole transport combination layer composed of a first hole transport layer (NiOₓ, 15 nm) and a second hole transport layer (2PACz, about 1 nm), which were stacked in order; a three-dimensional perovskite FAPbBr₃ layer (270 nm); an electron transport combination layer composed of a first electron transport layer (B4PYMPM, 5 nm), a hybrid electron transport layer (B4PYMPM: C₆₀, 5 nm), a second electron transport layer (C₆₀, 20 nm), and a third electron transport layer (BCP, 5 nm), which were stacked in order; and a silver electrode layer (100 nm). The specific preparation process for the above device was as follows:
(1) 0.1 mol/L solution of nickel acetate tetrahydrate in ethanol was prepared, and 0.1 mol/L ethanolamine was added to obtain an NiOₓ precursor solution. The NiOₓ precursor solution was dropwise added to an ITO substrate, spin-coated at a speed of 4000 rpm for 30 seconds, and annealed at 360° C. for 60 minutes to obtain an NiOₓ layer.
(2) 0.5 mg/mL solution of 2PACz in ethanol was prepared. The solution of 2PACz in ethanol was dropwise added to the NiOₓ layer prepared in step (1), spin-coated at a speed of 4000 rpm for 30 seconds, and annealed at 100° C. for 10 minutes to obtain a 2PACz layer.
(3) 0.13747 g of formamidine hydrobromide (FABr), 0.36701 g of lead bromide (PbBr₂), 0.00123 g of potassium 3-sulfopropyl methacrylate (SPM), 0.85 mL of dimethyl sulfoxide (DMSO), and 0.15 mL of N,N-dimethylformamide (DMF) were accurately weighed into a glass flask, and stirred overnight at room temperature to fully dissolve the solute, so as to prepare a perovskite precursor solution.
(4) The perovskite precursor solution prepared in step (3) was dropwise added to the 2PACz layer prepared in step (2) and spin-coated firstly at a speed of 500 rpm for 5 seconds and then at a speed of 4000 rpm for 20 seconds, 120 μL of a mixed solvent of chlorobenzene/ethyl acetate (v/v=3:1) was dropwise added 10 seconds before the end of the second step of spin-coating, and after annealing at 90° C. for 10 minutes, a perovskite layer was obtained.
(5) 5 nm B4PYMPM, 5 nm B4PYMPM: C₆₀ (v/v=0.5:1), 20 nm C₆₀, 5 nm BCP, and a 100 nm Ag electrode were evaporated layer by layer on the perovskite layer prepared in step (4) by a vacuum thermal evaporation method to obtain the photoelectric conversion device of this example.

### Comparative Example 1

This comparative example provided a photoelectric conversion device, comprising: sequentially from bottom to top, an ITO electrode layer (180 nm); a hole transport combination layer composed of a first hole transport layer (NiOₓ, 15 nm) and a second hole transport layer (2PACz, about 1 nm), which were stacked in order; a three-dimensional perovskite FAPbBr₃ layer (270 nm); an electron transport combination layer composed of a first electron transport layer (C₆₀, 20 nm) and a second electron transport layer (BCP, 5 nm), which were stacked in order; and a silver electrode layer (100 nm). The specific preparation process for the above device was as follows:
(1) 0.1 mol/L solution of nickel acetate tetrahydrate in ethanol was prepared, and 0.1 mol/L ethanolamine was added to obtain an NiOₓ precursor solution. The NiOₓ precursor solution was dropwise added to an ITO substrate, spin-coated at a speed of 4000 rpm for 30 seconds, and annealed at 360° C. for 60 minutes to obtain an NiOₓ layer.
(2) 0.5 mg/mL solution of 2PACz in ethanol was prepared. The solution of 2PACz in ethanol was dropwise added to the NiOₓ layer prepared in step (1), spin-coated at a speed of 4000 rpm for 30 seconds, and annealed at 100° C. for 10 minutes to obtain a 2PACz layer.
(3) 0.13747 g of formamidine hydrobromide (FABr), 0.36701 g of lead bromide (PbBr₂), 0.00123 g of potassium 3-sulfopropyl methacrylate (SPM), 0.85 mL of dimethyl sulfoxide (DMSO), and 0.15 mL of N,N-dimethylformamide (DMF) were accurately weighed into a glass flask, and stirred overnight at room temperature to fully dissolve the solute, so as to prepare a perovskite precursor solution.
(4) The perovskite precursor solution prepared in step (3) was dropwise added to the 2PACz layer prepared in step (2) and spin-coated firstly at a speed of 500 rpm for 5 seconds and then at a speed of 4000 rpm for 20 seconds, 120 μL of a mixed solvent of chlorobenzene/ethyl acetate (v/v=3:1) was dropwise added 10 seconds before the end of the second step of spin-coating, and after annealing at 90° C. for 10 minutes, a perovskite layer was obtained.
(5) 20 nm C₆₀, 5 nm BCP, and a 100 nm Ag electrode were evaporated layer by layer on the perovskite layer prepared in step (4) by a vacuum thermal evaporation method to obtain the photoelectric conversion device of this comparative example.

### Performance Test

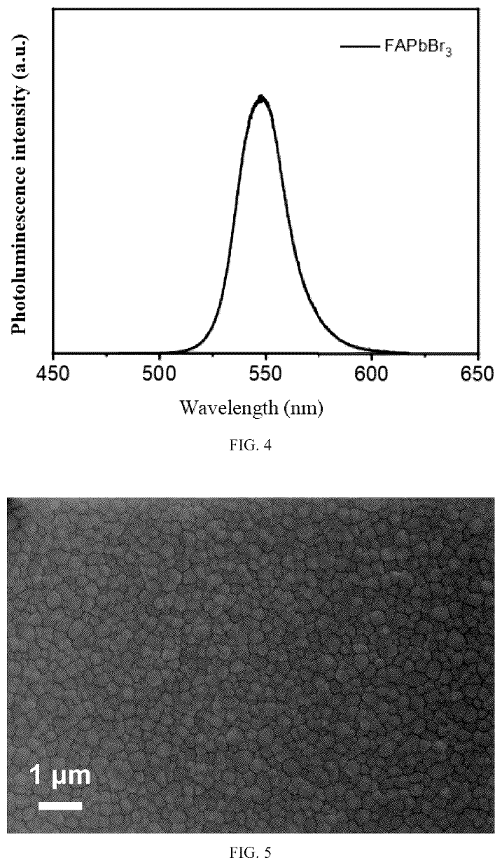

1) The ultraviolet-visible absorption spectrum and steady-state fluorescence spectrum of the FAPbBr₃ perovskite layer in Example 1 of the present disclosure were tested, and the test results were as shown in FIG. 3 and FIG. 4, respectively. As can be seen from FIG. 3, the perovskite layer has an obvious absorption peak of three-dimensional perovskite and can absorb visible light at 530 nm or less, thereby exciting carriers in the perovskite layer. As can be seen from FIG. 4, the perovskite layer shows a single photoluminescence peak (specifically green light) under ultraviolet illumination. Therefore, the perovskite material in the example of the present disclosure has good absorption and luminescent characteristics, which is beneficial to realize an efficient perovskite photovoltaic-luminescent dual function device.

2) The scanning electron microscope image of the FAPbBr₃ perovskite layer in Example 1 of the present disclosure was tested. The test results are as shown in FIG. 5, with the test scale bar being 1 μm. As can be seen from FIG. 5, the perovskite thin film shows a uniform thin film morphology and particle size distribution.

3) The photovoltaic performances of the devices of Examples 1 and 2 and Comparative Example 1 were tested. The test results are as shown in Table 1 and FIG. 6. The test conditions were carried out under a sunlight simulator, and the light intensity was AM1.5G. As can be seen from Table 1 and FIG. 5, compared with Comparative Example 1 in which C₆₀/BCP is used as an electron transport combination layer, the device of Example 1 in which B4PYMPM/C₆₀/BCP is used as an electron transport combination layer has an open circuit voltage that significantly increases from 1.22 V to 1.67 V, indicating that the structure of B4PYMPM/C₆₀/BCP is better matched with the energy level of the FAPbBr₃ perovskite layer, thus reducing the open circuit voltage loss. Furthermore, in Example 2, a hybrid layer was introduced between B4PYMPM and C₆₀, so that the energy level structure of the device can be further optimized, thereby improving the performance of the device. The perovskite dual-function device of Example 2 in which B4PYMPM/B4PYMPM: C₆₀/C₆₀/BCP is used as an electron transport combination layer has an open circuit voltage of 1.76 V, a short circuit current density of 7.50 mA cm-2, a filling factor of 48.94%, and a photoelectric conversion efficiency of 6.47%.

It can be seen that in Examples 1 and 2 of the present disclosure, by adjusting and controlling the electron transport layer and the hole transport layer, they have an energy level structure and energy level arrangement that is better matched with the FAPbBr₃ perovskite layer, whereby the performance of the device can be effectively optimized, and the device achieves a high open circuit voltage of 1.76V, maintains a good charge extraction capacity, and achieves a photoelectric conversion efficiency of more than 5%.

TABLE 1
Photovoltaic performance parameters of devices
of Examples 1 and 2 and Comparative Example 1

| | Open | | | Photoelectric |
|---|---|---|---|---|
| | circuit | Short circuit | Filling | conversion |
| | voltage | current | factor | efficiency |
| | (V) | (mA · cm⁻²) | (%) | (%) |
| Example 1 | 1.67 | 7.03 | 45.07 | 5.29 |
| Example 2 | 1.76 | 7.50 | 48.94 | 6.47 |
| Comparative | 1.22 | 8.22 | 70.20 | 7.05 |
| Example 1 | | | | |

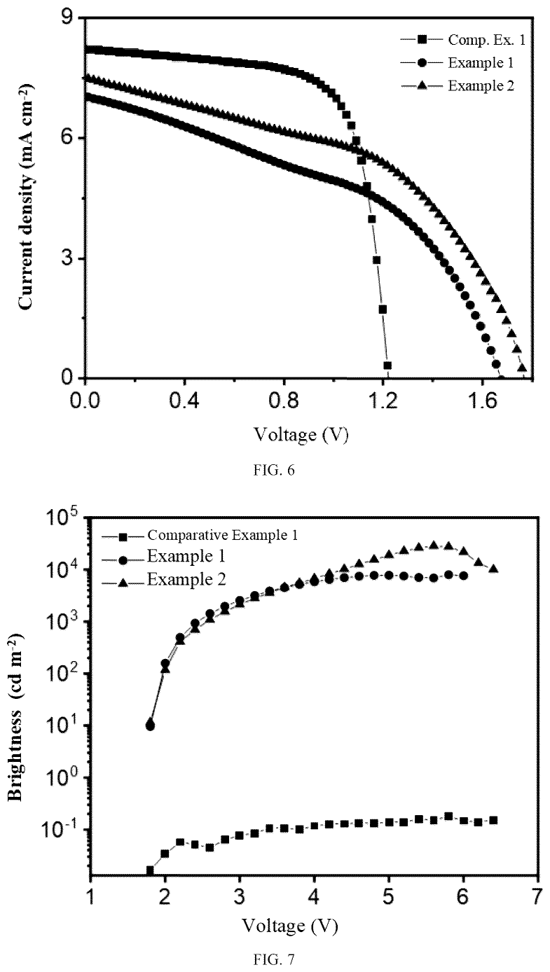

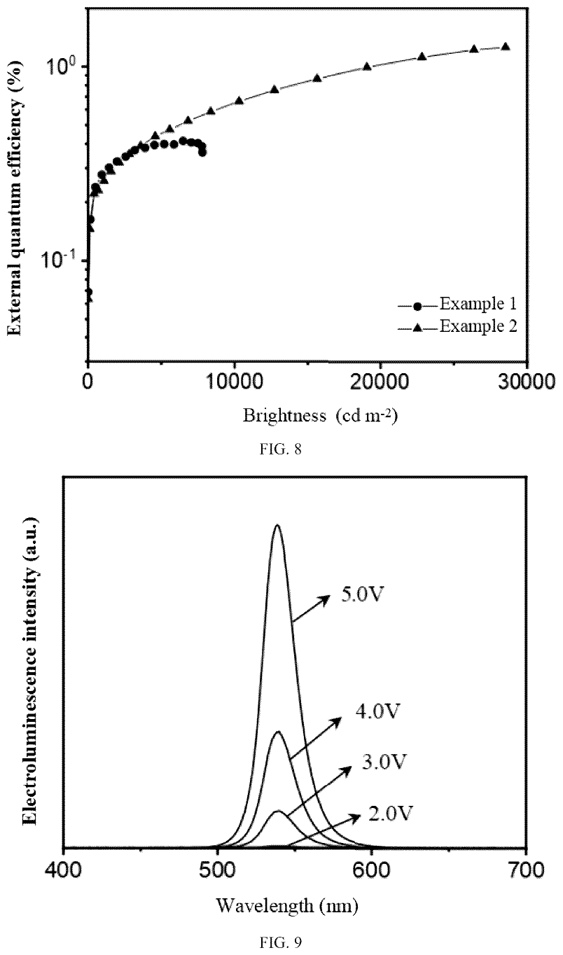

4) The electroluminescent properties of the devices of Examples 1 and 2 and Comparative Example 1 were tested. The performance parameters of the devices are as shown in Table 2, the brightness-voltage curves are as shown in FIG. 7, the external quantum efficiency-brightness curves are as shown in FIG. 8, and the electroluminescent spectrum of the device in Example 2 under different bias voltages are as shown in FIG. 9. As can be seen from Table 2 and FIG. 7, the device of Comparative Example 1 in which C₆₀/BCP is used as an electron transport combination layer cannot emit light when driven by an external voltage, whereas Example 1 in which a layer of B4PYMPM is introduced between the perovskite and C₆₀ can realize the electroluminescence of the device, with a maximum brightness of up to 7802 cd·m⁻² and a turn-on voltage as low as 1.8 V, indicating that electrons and holes were injected into the perovskite layer and underwent effective radiative recombination. Furthermore, in Example 2, the introduction of the hybrid layer between B4PYMPM and C₆₀ can optimize the energy level structure of the device. The maximum brightness of the device can be significantly increased to 28520 cd·m⁻², the external quantum efficiency gradually increases with the increase of brightness, and the maximum external quantum efficiency reaches 1.26%. As can be seen from FIG. 8, the perovskite dual-function device of Example 2 has a stable luminescence spectrum with a peak value of 540 nm in the visible band under different bias voltages.

It can be seen that in Examples 1 and 2 of the present disclosure, by adjusting and controlling the electron transport layer and the hole transport layer, they have an energy level structure and energy level arrangement that is better matched with the FAPbBr₃ perovskite layer, whereby the obtained device can have both photovoltaic and luminescent characteristics, can sensitively respond to optical signals, efficiently generate electricity under illumination, emit light with a low energy consumption in the dark, and have an efficient application effect.

TABLE 2
Electroluminescence performance parameters of devices
of Examples 1 and 2 and Comparative Example 1

| | | | Maximum | |
|---|---|---|---|---|
| | | | external | |
| | Turn-on | Maximum | quantum | Peak value |
| | voltage | brightness | efficiency | in spectrum |
| | (V) | (cd · m⁻²) | (%) | (nm) |
| Example 1 | 1.8 | 7802 | 0.41 | 540 |
| Example 2 | 1.8 | 28520 | 1.26 | 540 |
| Comparative | / | 0.18 | / | / |
| Example 1 | | | | |

In summary, the photoelectric reversible conversion dual-function device provided by the present application is simple to prepare and low in cost, and the structure of the hole transport combination layer and the electron transport combination layer as used in the structure of the device can be matched with the energy level of the perovskite layer so as to balance the extraction and injection of charges in the perovskite material. Free electrons and holes generated by the perovskite material under illumination can be extracted by the electron transport layer and the hole transport layer, respectively. Under the action of external bias voltages, the device can inject electrons and holes into the perovskite layer via the hole transport combination layer and the electron transport combination layer for radiative recombination, so that the device can realize photovoltaic-luminescent dual functions under different working mechanisms, and the luminescent wavelength is in the visible range. Therefore, the dual-function device of the present disclosure can be widely used in the fields of photovoltaics, lighting, display, etc.

The above examples are preferred embodiments of the present disclosure, and the embodiments of the present disclosure are not limited by the above examples. Any other changes, modifications, substitutions, combinations, and simplifications made without departing from the spiritual essence and principle of the present disclosure should all be equivalent replacements and are included in the scope of protection of the present disclosure.

What is claimed is:

1. A photoelectric conversion device, comprising a first electrode, a hole transport layer, a semiconductor functional layer, an electron transport layer, and a second electrode, which are stacked in order,
wherein a conduction band energy level of the electron transport layer is matched with a conduction band energy level of the semiconductor functional layer; and a valence band energy level of the electron transport layer is deeper than a valence band energy level of the semiconductor functional layer;
wherein a valence band energy level of the hole transport layer is matched with a valence band energy level of the semiconductor functional layer; and a conduction band energy level of the hole transport layer is shallower than a conduction band energy level of the semiconductor functional layer.

2. The photoelectric conversion device according to claim 1, wherein an energy level difference between the conduction band energy level of the electron transport layer and the conduction band energy level of the semiconductor functional layer is less than or equal to 0.5 eV; and
an energy level difference between the valence band energy level of the hole transport layer and the valence band energy level of the semiconductor functional layer is less than or equal to 0.5 eV.

3. The photoelectric conversion device according to claim 1, wherein the semiconductor functional layer comprises a direct bandgap semiconductor material; and the direct bandgap semiconductor material comprises at least one of a metal halide perovskite, gallium nitride, cadmium selenide, or indium phosphide.

4. The photoelectric conversion device according to claim 3, wherein the metal halide perovskite has a chemical formula of AMX₃ or L₂Aₙ₋₁MₙX₃ₙ₊₁;
wherein A represents a monovalent cation and includes at least one of Cs⁺, Rb⁺, MA⁺, FA⁺, or GA⁺;
M represents a divalent cation and includes at least one of Pb²⁺, Sn²⁺, Mn²⁺, Ca²⁺, or Zn²⁺;
X represents a monovalent anion and includes at least one of F⁻, Cl⁻, Br⁻, I⁻, (BF⁴)⁻, or SCN⁻;
L represents a monovalent cation and includes at least one of EA⁺, PA⁺, i-PA⁺, BA⁺, i-BA⁺, t-BA⁺, HA⁺, OA⁺, PhA⁺, PMA⁺, PEA⁺, PPA⁺, or NMA⁺;
n is 1 to 10.

5. The photoelectric conversion device according to claim 1, wherein the electron transport layer comprises at least one of the following layer structures:
a first electron monolayer structure composed of a first electron transport layer;
a second electron multilayer structure composed of a first electron transport layer and a second electron transport layer, which are stacked;
a third electron multilayer structure composed of a first electron transport layer, a second electron transport layer and a third electron transport layer, which are stacked in order; and
a fourth electron multilayer structure composed of a first electron transport layer, a hybrid electron transport layer, a second electron transport layer, and a third electron transport layer, which are stacked in order;
wherein the first electron transport layer, the second electron transport layer, and the third electron transport layer each independently comprise at least one electron transport material; and the hybrid electron transport layer comprises at least two electron transport materials.

6. The photoelectric conversion device according to claim 5, wherein the first electron transport layer has a thickness of 0.5 nm to 20 nm.

7. The photoelectric conversion device according to claim 5, wherein the second electron transport layer has a thickness of 5 nm to 30 nm.

8. The photoelectric conversion device according to claim 5, wherein the third electron transport layer has a thickness of 0.5 nm to 20 nm.

9. The photoelectric conversion device according to claim 5, wherein the hybrid electron transport layer has a thickness of 0 nm to 20 nm.

10. The photoelectric conversion device according to claim 5, wherein the hybrid electron transport layer comprises a first electron transport material and a second electron transport material; and a mass ratio of the first electron transport material to the second electron transport material is (0.1 to 10): 1.

11. The photoelectric conversion device according to claim 1, wherein the electron transport layer comprises an electron transport material;
the electron transport material comprises at least one of 1,3,5-tris(1-phenyl-1H-benzimidazol-2-yl)benzene, 2,4,6-tris[3-(diphenylphosphino)phenyl]-1,3,5-triazine, 4,6-bis(3,5-bis(pyridin-3-yl)phenyl)-2-methylpyrimidine, 4,6-bis(3,5-bis(pyridin-4-yl)phenyl)-2-methylpyrimidine, tris[2,4,6-trimethyl-3-(3-pyridinyl)phenyl]borane, 2,9-dimethyl-4,7-biphenyl-1,10-phenanthroline, fullerene C₆₀, fullerene C₇₀, [6,6]-phenyl-C₆₁-butyric acid methyl ester, [6,6]-phenyl-C₇₁-butyric acid methyl ester, 2,7-bis(3-(dimethylamino) propyl)benzo[LMN][3,8]phenanthroline-1,3,6,8 (2H,7H)-tetrone, zinc oxide, or tin dioxide.

12. The photoelectric conversion device according to claim 1, wherein the hole transport layer comprises at least one of the following layer structures:
a first hole monolayer structure composed of a first hole transport layer; and
a second hole multilayer structure composed of a first hole transport layer and a second hole transport layer, which are stacked;
wherein the first hole transport layer and the second hole transport layer each independently comprise at least one hole transport material.

13. The photoelectric conversion device according to claim 1, wherein the hole transport layer comprises a hole transport material;
the hole transport material comprises at least one of poly(ethylenedioxythiophene)-poly(styrene sulfonate), nickel oxide, molybdenum trioxide, poly[bis(4-phenyl)(2,4,6-trimethylphenyl)amine], poly(9-vinylcarbazole), poly[(9,9-di-n-octylfluorenyl-2,7-diyl)-alt-(4,4′-(N-(4-n-butyl)phenyl)-diphenylamine)], 2,2′,7,7′-tetra[N,N-bis(4-methoxyphenyl)amino]-9,9′-spirobifluorene, [2-(9H-carbazol-9-yl)ethyl]phosphoric acid, [4-(9H-carbazol-9-yl)butyl]phosphoric acid, [2-(3,6-dimethoxy-9H-carbazol-9-yl)ethyl]phosphoric acid, [4-(3,6-dimethoxy-9H-carbazol-9-yl)butyl]phosphoric acid, or [4-(3,6-dimethyl-9H-carbazol-9-yl)butyl]phosphoric acid.

14. The photoelectric conversion device according to claim 1, wherein the first electrode has a thickness of 1 nm to 200 nm.

15. The photoelectric conversion device according to claim 1, wherein the hole transport layer has a thickness of 0.5 nm to 30 nm.

16. The photoelectric conversion device according to claim 1, wherein the semiconductor functional layer has a thickness of 50 nm to 2000 nm.

17. The photoelectric conversion device according to claim 1, wherein the electron transport layer has a thickness of 0.5 nm to 100 nm.

18. The photoelectric conversion device according to claim 1, wherein the second electrode has a thickness of 1 nm to 200 nm.

19. A photoelectric conversion apparatus comprising the photoelectric conversion device according to claim 1.

20. A method for preparing the photoelectric conversion device according to claim 1, comprising sequentially preparing the first electrode, the hole transport layer, the semiconductor functional layer, the electron transport layer, and the second electrode to obtain the photoelectric conversion device.
